(19) United States
(12) Patent Application Publication
(10) Pub. No.: US 2002/0079534 A1
(43) Pub. Date: Jun. 27, 2002

(54) Power semiconductor switching devices with low power loss and method for fabricating the same

(75) Inventors: Baowei Kang, Beijing (CN); Yu Wu, Beijing (CN); Xu Cheng, Beijing (CN); Zhe Wang, Beijing (CN)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: Beijing Polytechnic University, Beijing (CN)

(21) Appl. No.: 10/017,734

(22) Filed: Dec. 18, 2001

(30) Foreign Application Priority Data
Dec. 21, 2000 (CN) 00135808.1

(51) Int. Cl. H01L 21/8238; H01L 31/062; H01L 29/76

(52) U.S. Cl. 257/327; 257/329; 438/212

(57) ABSTRACT

A low-power-loss power semiconductor switching device and its fabricating method are proposed to provide a low-power-loss IGBT, MCT, or GTO with a voltage rating of less than 2 kV, wherein said device includes a combination of an ultra-thin lightly-doped back-side p⁺ emitter formed by ion implanting and a nonuniformly-doped n-type base layer which contains a residual layer of a priorly-diffused n⁺ layer on one side. And in accordance with said method, the residual diffused-layer near the p⁺ emitter contained in the nonuniformly doped base is formed in the first step of the fabricating process before the thinning of the substrate. After the thinning of the substrate, only low-temperature processes occur. This invention combines the feature of low on-voltage of a PT-IGBT and the feature of short switching time of an NPT-IGBT, and is very applicable to practical manufacturing.

### FIELD OF THE INVENTION

This invention relates to a kind of power semiconductor switching device and its fabricating method. A power semiconductor switching device herein mentioned refers to an insulated gate bipolar transistor (IGBT), a MOS controlled thyristor (MCT), or a gate turn-off thyristor (GTO). The voltage rating of said power semiconductor device is in a middle and low range as under 2 kV.

### BACKGROUND OF THE INVENTION

Power semiconductor switching devices are used in power electronic applications. The most important requirement for them is that it should dissipate a low power loss. To meet this, the on-voltage of a device must be diminished to lower its on-state power loss, and the switching time must be shortened to decrease its switching loss. Taking the IGBT as an example, this issue will be explained in greater detail as follows.

Generally speaking, IGBTs fall into two basic types: the punchthrough IGBT (PT-IGBT) and the non-punchthrough IGBT (NPT-IGBT). IGBTs made in early days belong to the PT type (referring to IEDM Tech. Dig., pp. 264-267, 1982, and IEEE Trans. on Power Electronics, vol. PE-2, no. 3, pp. 194-207). The fabricating process of a PT-IGBT begins with a uniformly-doped p⁺ silicon substrate with a thickness of several hundred microns. Then follow the epitaxial growths of an n⁺ buffer layer and an n⁻ base layer in succession on the front side of the p⁺ substrate. A completed PT-IGBT comes into being when the complicated structure as a DMOS is formed in the surface region of the n⁻ base layer. It is worth pointing out that high voltage IGBTs normally need thick n⁻ layers. For example, a 1 kV IGBT requires an n⁻ thickness of 100 μm or more. A thick-layer epitaxy to form the thick n⁻ layer, however, is difficult to be perfect and therefore increases the manufacturing cost. Thereafter, the NPT-IGBT emerged in late 1980s (referring to IEEE PESC Record 1, pp. 21-25, 1989, and Proc. of ISPSD'96, pp. 331-334 and 169-172) which does not need the thick-layer epitaxial technique and is formed on the basis of an n⁻ monocrystal substrate. In the process of fabricating an NPT-IGBT, it is after the frontside structure is completed that the n⁻ substrate is ground and chemically etched from its backside to an appropriately thinned thickness, and then an ion implanting process is employed to form the backside p⁺ emitter (or IGBT collector). For high voltage IGBTs which need thick n⁻ layers, this epitaxy-free process is very preferable to that for PT-IGBTs. However, from the viewpoint of the power loss, both PT- and NPT-IGBTs are imperfect: the on-voltage of a PT-IGBT is lower but its switching time is longer; on the contrary, an NPT-IGBT has a shorter switching time but its on-voltage is higher. For a long period of time, it has been an attractive aim for researchers to invent a kind of technique to fabricate a new type of IGBT, the on-voltage of which is as small as that of a PT-IGBT while the switching time of which is as short as that of an NPT-IGBT. Theoretically, the on-voltage of a PT-IGBT is lower because its n⁻ base layer is thinner due to the presence of the n⁺ buffer layer which is usually 10-20 μm thick, while an NPT-IGBT, on the other hand, is based on a thicker and uniformly doped n⁻ substrate without the n⁺ buffer layer. The switching time of an NPT-IGBT is shorter because its backside p⁺ emitter formed by ion implanting is very thin and its doping concentration is low, which makes the injection efficiency of the backside p⁺ −n⁻ junction low enough to keep a high electron current component flowing out to the backside electrode (IGBT collector or anode). At the same time, the backside emitter of a PT-IGBT is the thick, uniformly and heavily doped p⁺ substrate which provides a high injection efficiency and a very small electron current component. The thickness of the p⁺ layer is inevitably large because it is used as a substrate during fabricating therefore must have enough mechanical strength to avoid wafer breakage. Additionally, the doping concentration of the p⁺ substrate or emitter cannot be lowered to decrease the injection efficiency because it will increase the resistance on the flowing path of the IGBT collector current. In order to obtain an IGBT with both low on-voltage and short switching time, an effective way is to employ both the n⁺ buffer layer and the thin and lightly doped backside p⁺ emitter in one and the same IGBT structure. This kind of IGBT was proposed in 1995 (U.S. Pat. No. 5668385). Starting from a uniformly-doped n⁻ substrate, it is made by fabricating the complicated frontside structure on one side of the substrate and at high temperatures diffusing, in succession, an n⁺ buffer layer of 30 tlm or more and a backside p⁺ emitter layer of 1.2 μm on the other side. Nevertheless, also implied by the inventors themselves, this structure (or the technique) applies preferably to very-high-voltage (e.g. 4.5 kV) devices. The reason is that since both sides endure high- temperature and long-time processes, the n⁻ substrate must be thick enough to avoid wafer breakage. A thickness of 400 μm or more for IGBTs with voltage ratings down to 4.5 kV just belongs to this case. However, middle- or low-voltage-IGBT (e.g. <2 kV) wafers with an n⁻-substrate thickness of only approximately 100-200 μm, cannot survive the multiple high-temperature processes. Since most of the commercially available IGBTs are with voltage ratings of 2 kV and lower, from the viewpoint of practical needs, the abovementioned patent has not actually attained the long-time-pursued aim of producing a low-power-loss IGBT. Recently in 2000, along with a 1.3 kV IGBT product, a method to produce IGBTs with voltage ratings of less than 2 kV and with both an n⁺ buffer layer and an ultra-thin lightly-doped backside p⁺ emitter was presented (see Proc. of ISPSD'2000, pp. 355-358). Beginning with a thick and uniformly doped n⁻ substrate, the frontside structure is formed by long-time and high-temperature processes, and then the substrate is thinned to a required thickness from its backside. Thereafter the n⁺ buffer layer and backside p⁺ emitter are formed by ion implanting into its backside and without any long-time and high-temperature processes. Using this technique, since there is no long-time and high-temperature process after the wafer is thinned to a small thickness, even a finally 100-μm-thick wafer will not break if carefully treated in final stages of the process (see Proc. ISPSD'97, pp. 361-364). For instance, the final substrate thickness of the 1.3 kV IGBT product mentioned above is only 110 μm and it does not matter. On the other hand, however, the n⁺ buffer layer of this kind of IGBT is too thin and its thickness usually cannot be easily realized as more than 1 μm. This is because at the time when the dopant for the buffer layer is implanted, the frontside structure of the IGBT, the source junction depth of which may be submicron, has already formed on the other side of the n⁻ substrate and any attempt made to anneal and drive in the n⁺ buffer layer at high temperatures will fail due to the changes in junction depths of the frontside DMOS structure and thus the characteristic worsening of the DMOS. Furthermore, wafers with such a thickness as approximately 100 μm will tend to break when treated at high temperatures. Such inevitably thin (not more than 1 μm) an n⁺ buffer layer of this technique is unfortunately impractical in real manufacturing. When high voltages applied, this thin n⁺ buffer layer acts as a field-stop layer but cannot reserve a “field-free” region thick enough to keep the leakage current at a low level and the breakdown characteristic will perform softly. Moreover, inevitably introduced mechanical damage and unavoidable crystal defects on the backside of the substrate also contribute to a failure of the field-stop function of the n⁺ buffer layer and result in bad characteristics of the device. The authors of this ISPSD paper also pointed out that the leakage current and breakdown voltage of the device cannot be easily guaranteed. This kind of IGBT, therefore, cannot be actually or easily fabricated as commercialized products. In other words, although some solutions seems available, there is still no practical technique by far for the most commercially needed IGBTs with voltage ratings of less than 2 kV to achieve further decreased power loss resulted from both lowered on-voltage and shortened switching time. For MCTs and GTOs, this problem also exists.

### DESCRIPTION OF THIS INVENTION

The object of this invention, thereby, is to provide a kind of low-power-loss IGBT with a voltage rating of less than 2 kV and a practical method for fabricating the same. In accordance with the invention, this kind of IGBT combines the feature of low on-voltage of a PT-IGBT and the feature of short switching time of an NPT-IGBT, and its fabricating method can realize a stop layer and a backside emitter of proper thicknesses and concentrations in a way practical manufacturing can be developed. Moreover, this technique also can be applied to MCTs and GTOs.

To attain the abovementioned object, this invention proposes a low-power-loss power semiconductor switching device (either an IGBT, MCT or GTO) comprising an n-type base, a backside p⁺ emitter and a general frontside structure including a cathode and a gate, wherein said switching device includes a combination of an ultra-thin and lightly-doped backside p⁺ emitter formed by ion implanting and a nonuniformly doped n-type base which contains a residual layer of a priorly-diffused n⁺ layer on one side of the device. That is to say, the device proposed herein comprises the following three components: a nonuniformly-doped n-type base containing a residual layer of a priorly-diffused n⁺ layer wherein the doping concentration decreases from one side to another; an ultra-thin lightly-doped backside p⁺ emitter formed by ion implanting on the high-concentration side of the n-type base; and a general frontside structure including cathode and gate regions formed on the low concentration side (opposite to the high-concentration side) of the n-type base.

In the low-power-loss power semiconductor switching device proposed herein, the thickness of the backside p⁺ emitter is in a range of 0.1˜1.0 μm, and the implanting dose for it is in a range of 1×10¹¹˜1×10¹⁷ cm⁻², preferably 5×10¹³˜1×10¹⁵ cm⁻². For example, the thickness and implanting dose can be chosen to be 0.2, 0.4, 0.6, or 0.8 μm, and 5×10¹³, 1×10¹⁴, 5×10¹⁴, or 1×10¹⁵ cm⁻², respectively, according to the required on-voltage. Furthermore, the doping profile of the n-type base is such that the doping concentration decays from the interface of the base and backside p⁺ emitter, and after arriving at the interior boundary of the residual diffused-layer contained in the n-type base, the doping concentration nearly remains constant until the frontside structure region is reached. The residual diffused-layer usually takes a thickness in a range of 5˜50 μm. With various voltage ratings, it can be chosen to be, e.g. 5, 10, 15, 25, 30, 35 μm, or other. The doping concentration of the n-type base at the interface of the residual layer and backside p⁺ emitter is between 1×10¹⁴ and 1×10¹⁷ cm⁻³. The total thickness of the n-type base varies with different voltage ratings, typically designed to be 100 μm for a 1000 V breakdown and 200 μm for a 2000 V breakdown. The detailed frontside structure may be that of an IGBT, MCT or GTO, planar type or trench type, with no special limitations being set.

The fabricating method for achieving this kind of lower-power-loss switching device is in accordance with the following sequenced procedures.

PROCEDURE I: Fabricating a nonuniformly-doped n-type substrate which contains a diffused n⁺ layer on the backside. The diffused layer is formed in the first step of this procedure when certain n-type dopant is heavily diffused into both sides of an n⁻ substrate at the same time. One (on the final frontside) of the two diffused layers is then removed by grinding and the exposed surface of the n⁻ substrate is further ground and polished to a proper position according to the required voltage rating of the device, thus the nonuniformly-doped n-type substrate containing a diffused n⁺ layer (on the final backside) is achieved. Of course, the doping concentration decays from the backside to the frontside.

PROCEDURE II: Fabricating the general frontside structure on the low-concentration side (the frontside) of the n-type substrate formed in PROCEDURE I by use of ion implanting, high-temperature diffusion, CVD, evaporation/sputtering, and so on.

PROCEDURE III: Thinning the substrate from the high-concentration side (the backside) to a position determined according to the required voltage rating by such commonly used techniques as grinding and chemical etching. The residual layer of the priorly diffused n⁺ layer on the backside is then formed.

PROCEDURE IV: Forming the backside p⁺ emitter of proper thickness by ion implanting into the surface of the residual diffused-layer. Adjusting the implanting dose to make the switching time as short as possible while the on-voltage does not exceed a predefined limit.

PROCEDURE V: Depositing metals on the surface of the backside p⁺ emitter, followed by sintering/alloying.

It can be seen from the abovementioned procedures that after the substrate is thinned, i.e. after PROCEDURE III or since PROCEDURE IV, only low-temperature processes occur. Said low temperature is considered to be less than 600 ° C.

Meeting the requirements of the object of this invention, the proposed technical solution including the structure design and its fabricating method can produce desirable power semi-conductor switching devices with both lowered on-voltages and shortened switching times. When a high voltage applied, the residual layer (of the priorly diffused n⁺ layer) contained in the n-type base can act as a field-stop layer due to its high doping concentration. Therefore, for the same voltage rating, the proposed structure can take a thinner n⁻ layer than that without a stop layer, i.e. that of an NPT-IGBT. This would be notably advantageous in terms of on-voltage. Since the function of the highly-doped and concentration-graded residual layer is the same as that of the n⁺ buffer layer in a PT-IGBT, the on-voltage of the proposed structure should be at the same and lowered level as that of a PT-IGBT. A stop-layer thickness of 25-50 μm is appropriate for a 2000 V device. If too thick, the on-stage will increase; if too thin, the field-stop function will be weakened which will result in a degraded breakdown voltage or an increased leakage current. On the other hand, this invention suggests an ultra-thin and lightly doped backside emitter with a thickness of less than 1 μm such that the electron current flowing though the backside emitter junction will be much larger than that in a PT-IGBT. Thus, the excess electrons stored in the n-type base can be easily drawn out through the backside emitter during the turn-off. It is in this way that the switching time is shortened. Since this backside emitter is just the same as that of an NPT-IGBT, it can be predicted that this structure will be capable of the same shortened switching time as that of an NPT-IGBT.

Besides the features mentioned above, this invention is also very applicable in practical manufacturing due to the proposed fabricating method. As previously mentioned, for a power switching device with a voltage rating of less than 2 kV, the n-type base containing an n⁺ field stop layer in it normally takes a thickness equal to or less than 200 μm. Such thin a wafer cannot survive and tends to break in a high-temperature and long-time process. Therefore, the method proposed by the background document of U.S. Pat. No. 5668385, which requires high-temperature diffusions on both sides of the wafer, cannot be applied to the presently proposed structure, whilst the presently proposed method can. Referring to the fabricating procedures described above, although the final thickness of the wafer is equal to or less than 200 μm, Procedure I provides a larger thickness of several hundred microns which is contributed by an n⁻ layer plus a diffused n⁺ layer. The total thickness will be large enough to stand the following processes if the n⁺ layer is diffused deeply enough thus avoiding high-temperature treatments to a thinned wafer Normally, a long-time diffusion can produce a diffused layer of 200 μm or more, then the total wafer thickness should be 300-400 μm thick or more. With wafers of such a thickness, Procedure II (to produce the frontside structure) can be smoothly processed without any danger of wafer breakage. A thinned wafer thickness of 100-200 μm will be produced or processed during Procedure III-V, but there are no high temperatures, and some existing techniques (referring to Proc. of ISPSD'97, pp. 361-364) can help to minimize the breakage possibility to a very low level.

### BRIEF DESCRIPTION OF THE DRAWINGS

FIG. 1 is a cross section of the basic structure proposed by the invention for an IGBT.

FIG. 2 shows the steps of the fabricating process for forming the structure of FIG. 1.

### DESCRIPTION OF PREFERED EMBODIMENTS

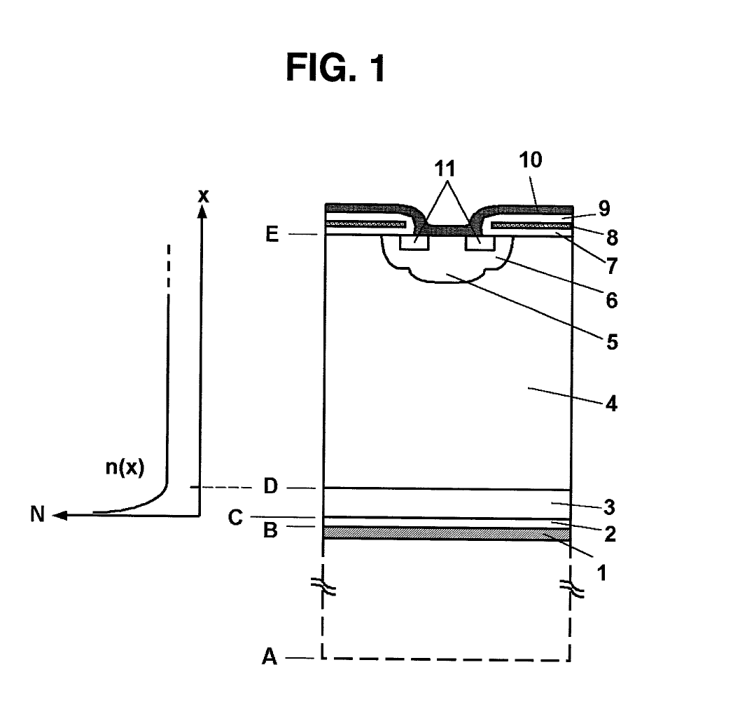

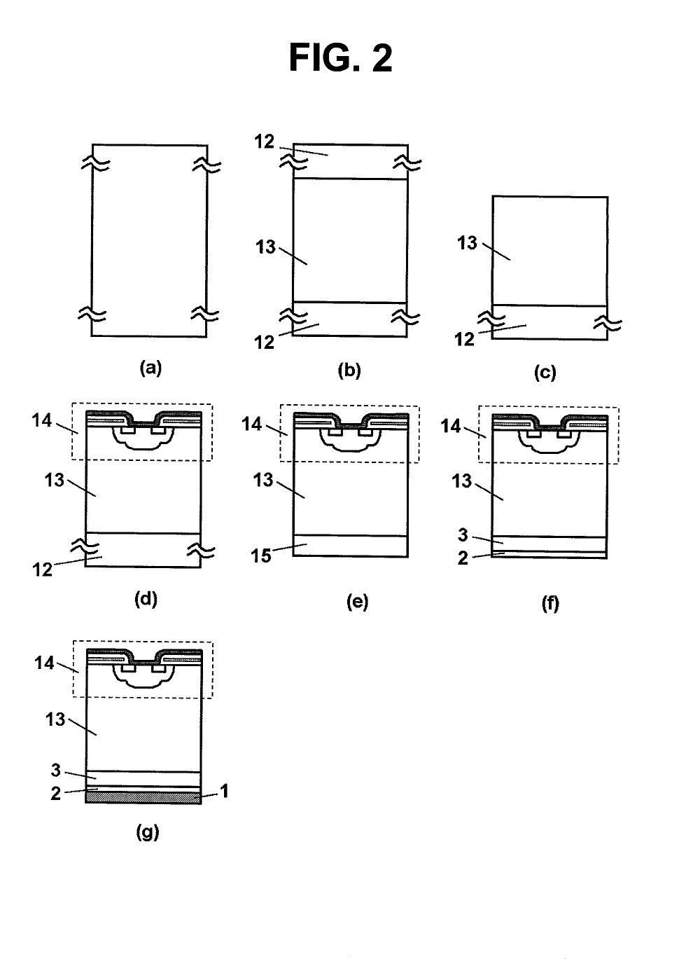

One of the preferred embodiments of the invention is to produce a low-power-loss IGBT as shown in FIGS. 1 and 2. This IGBT, referring to FIG. 1, is formed on an n-type substrate A-E, and its thickness is 300 μm or more. It comprises a uniformly doped n⁻ region 4, the thickness of which is determined by the required voltage rating, and a diffused n⁺ layer A-D, in which the doping concentration is graded from the backside surface A to the n⁺/n³¹ interface D and layer A-B is removed during the fabricating process (in Procedure III mentioned above) with a residual layer B-D remaining. Ion implanting with a dose of 1×10¹¹˜1×10¹⁷ cm⁻² (preferably 5×10¹³˜1×10¹⁵ cm⁻²) upon the surface B results in a backside p⁺ emitter 2 with a thickness of less than 1 μm, and the final residual layer 3 of the priorly-diffused n⁺ layer A-D acting as an n⁺ field-stop layer and taking a thickness of 5 50 μm. Layers 3 and 4 constitute the final nonuniformly-doped n-type base and its doping profile is shown in the plot near the cross section of the structure in FIG. 1. As the anode electrode, metallization system 1 is formed on the surface B of the backside emitter. The frontside structure, a commonly used IGBT frontside structure 5-11, consists of a p⁺ collector region 5, a p-well 6, a gate oxide layer 7, a gate electrode 8, an insulated layer 9 between electrodes, an anode electrode 10, and n⁺ source regions 11. This frontside structure is of the planar type. Other types, a typical example of which is the trench gate structure, are also permissible.

In the structure shown in FIG. 1, there is a strong electric field existing in the n⁻ doped voltage-withstanding layer 4 at high voltages. Stop layer 3 due to its high doping concentration can rapidly lower this strong filed and reserve a “field free” region of curtain thickness to minimize the leakage current and guarantee a hard characteristic of the device breakdown. Because of the presence of the stop layer 3, a thinner n⁻ layer 4 can achieve the same voltage rating as that of an NPT-IGBT which takes a thicker n⁻ layer, whereas contribute a low on-voltage like a PT-IGBT does. On the other hand, the backside p⁺ emitter 2 formed by ion implanting takes a much thinner thickness and a lower doping concentration compared with those of a PT-IGBT and thus results in a larger electron current flowing out of the backside emitter 2. This provides a smooth path for the excess electrons stored in the n-type base 3 and 4 to be drawn out during turn-off (the excess holes flows out through the p⁺ collector 5. So the switching time should be shorter than that of a PT-IGBT. Moreover, since the backside emitter is the same as that of an NPT-IGBT but the n⁻ layer 4 is thinner storing a smaller amount of excess charges, the switching time should be as short as that of an NPT-IGBT or even shorter.

In FIG. 1, if components 5-11 are changed to the frontside structure of an MCT or GTO and the other parts 1-4 are kept as they were, a low-power-loss MCT or GTO with both low on-stage and fast switching will also be achieved.

In accordance with the fabricating procedures mentioned previously, FIG. 2 shows the process steps to form the proposed low-power-loss IGBT, wherein:

FIG. 2(a) gives the starting n monocrystal substrate with a very large thickness and a resistivity determined by the required voltage rating;

FIG. 2(b) shows the situation after the starting substrate undergoes a double-sided n-type diffusion, presenting two diffused n⁺ layers 12 on both sides of the n⁻ monocrystal layer 13, where the depth of diffusion guarantees that the thickness sum of the n⁻ layer 13 plus one of two diffused layers 12 is equal to or more than approximately 300 μm;

FIG. 2(c) presents a nonuniformly-doped n-type substrate after the wafer shown in FIG. 2(b) is processed by grinding and polishing to remove one of the diffused n⁺ layers 12 and continue to reduce the thickness of the n⁻ monocrystal layer 13 to the smallest value determined by the required voltage rating;

FIG. 2(d) describes the wafer after a series of high-temperature and long-time treatments with which forms the fronside structure 14 (specified in FIG. 1 with components 5-11) of the IGBT on the frontside of the substrate (i.e. on the exposed surface of the n⁻ monocrystal layer 13);

FIG. 2(e) illustrates the case after the wafer is thinned by grinding and etching from its backside (opposite to the frontside of the substrate), where the residual layer 15 of the priorly diffused layer 12 is a little thicker than the final residual layer 3 (shown in FIG. 1 and FIGS. 2(f) and 2(g));

The resultant structure after the backside p⁺ emitter 2 is formed by ion implanting on the surface of the residual layer 15 (shown in FIG. 2(e)) is shown FIG. 2(f), where the thickness of the backside emitter 2 (equal to the thickness difference between those of layers 15 and 3) is less than 1 μm and its implanting dose can be adjusted according to the required onvoltage, normally ranging from 1×10¹¹ to 1×10¹⁷ cm⁻², but preferably from 5×10¹³ to 1×10¹⁵ cm⁻²;

FIG. 2(g) exhibits the final structure of the IGBT, where the metalization system of the backside anode electrode is formed by commonly used methods such as evaporation, sputtering, etc, and completed by alloying/sintering at a temperature of less than 600° C.

When this invention applied to MCTs or GTOs, what is only needed to do is to change the front structure 14 and its fabricating method to the corresponding structure and method.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed here is:

1. A low-power-loss power semiconductor switching device comprising an n-type base, a backside p⁺ emitter and a general frontside structure including a cathode and a gate, wherein said switching device includes a combination of an ultra-thin and lightly-doped backside p⁺ emitter formed by ion implanting and a nonuniformly doped n-type base which contains a residual layer of a priorly-diffused n⁺ layer on one side of the device.

2. The switching device as defined in claim 1 wherein the thickness of the backside p⁺ emitter is approximately between 0.2 and 1 μm.

3. The switching device as defined in claim 1 wherein the implanting dose of the backside p⁺ emitter is approximately between 1×10¹¹and 1×10¹⁷ cm⁻².

4. The switching device as defined in claim 1 wherein the thickness of the n-type residual diffused-layer contained in the n-type base is approximately between 5 and 50 μm.

5. The switching device as defined in claim 1 wherein the doping concentration of the n-type residual diffused-layer is in a range of approximately 1×10¹⁴˜1×10¹⁷ cm⁻³ at the interface of the residual layer and the backside p⁺ emitter

6. A method for fabricating low-power-loss power semiconductor switching devicse, wherein the fabrication is in the following sequence:
PROCEDURE I: fabricating a nonuniformly doped n-type substrate which contains a diffused n⁺ layer on one side, wherein the diffused layer, which is finally near to the backside p⁺ emitter, is formed in the first step of this procedure before the thinning of the substrate;
PROCEDURE II: fabricating the general frontside structure of either an IGBT, MCT, or GTO on the low-concentration side of the n-type substrate using ion implanting, hightemperature diffusion and so on;
PROCEDURE III: thinning the wafer from the high-concentration side of the substrate by such commonly used techniques as grinding and polishing, so that the thickness of the residual diffused-layer is decreased to a required value;
PROCEDURE IV: forming the backside p⁺ emitter with a required thickness by ion implanting into the surface of the residual diffused-layer;
PROCEDURE V: depositing metals on the surface of the backside p⁺ layer, followed by sintering/alloying; and
after the substrate is thinned, i.e. after PROCEDURE III or since PROCEDURE IV, only low-temperature processes occur.

7. The method as defined in claim 6, wherein said low temperature is considered to be less than 600° C.
